(19) United States
(12) Patent Application Publication
(10) Pub. No.: US 2018/0287017 A1
(43) Pub. Date: Oct. 4, 2018

(54) LIGHT EMITTING DEVICES WITH A PLURALITY OF RECESSES

(71) Applicant: Everlight Electronics Co., Ltd., New Taipei City (TW)

(72) Inventors: Chien-Nan Liu, New Taipei City (TW); Chun-Ming Lai, New Taipei City (TW); Yan-Shen Lin, New Taipei City (TW); Kuang-Mao Lu, New Taipei City (TW); Ya-Chin Tu, New Taipei City (TW); Yung-Chieh Chen, New Taipei City (TW)

(73) Assignee: Everlight Electronics Co., Ltd., New Taipei City (TW)

(21) Appl. No.: 15/940,994

(22) Filed: Mar. 30, 2018

Related U.S. Application Data
(60) Provisional application No. 62/479,345, filed on Mar. 31, 2017.
(60) Provisional application No. 62/505,991, filed on May 15, 2017.
(60) Provisional application No. 62/535,246, filed on Jul. 21, 2017.
(60) Provisional application No. 62/590,285, filed on Nov. 23, 2017.

(51) Int. Cl. H01L 33/48; H01L 27/15; H01L 33/62

(52) U.S. Cl. CPC H01L 33/486; H01L 33/507; H01L 33/62; H01L 27/153

(57) ABSTRACT

The present invention is directed to a light emitting device that includes an elongated package defining a plurality of recesses and a plurality of light emitting units to be disposed in the recesses. The package includes at least three electrodes and a molded body. At least one light emitting unit is disposed in each recess. The molded body has at least one dividing portion separating two adjacent recesses. The dividing portion partially covers the electrode shared by the light emitting diodes respectively disposed in two adjacent recesses.

### CROSS REFERENCE

This application claims priority to U.S. provisional patent application No. 62/479,345, filed on Mar. 31, 2017; U.S. provisional patent application No. 62/505,991, filed on May 15, 2017, U.S. provisional patent application No. 62/535,246, filed on Jul. 21, 2017, and U.S. provisional patent application No. 62/590,285, filed on Nov. 23, 2017, the entire disclosure of which is herein incorporated by reference.

### BACKGROUND OF THE INVENTION

### Field of Invention

The present invention relates to a light emitting device with a package in which a plurality of light emitting units can be disposed in two or more separate recesses.

### Description of Related Art

Light emitting diodes (“LEDs”) have many advantages over incandescent light sources, including lower energy consumption (more energy efficient), longer lifetime, improved physical robustness, smaller size, and faster switching. As a result, LEDs are used in applications as diverse as aviation lighting, automotive headlamps, advertising, general lighting, traffic signals, camera flashes, lighted wallpaper and medical devices. LEDs can be mounted on various kinds of package structures depending on their intended uses. For example, LEDs are widely used as backlight illumination for flat display panels, such as TFT LCD panels, in various consumer electronics, including mobile phones, TVs, etc. In this application, LED packages, usually side-view type, are arranged at an edge of alight guide plate to emit light parallel to the light guide plate. However, a conventional LED package has only one recess in which an LED is electrically connected with two electrodes to emit light of single color.

### SUMMARY OF THE INVENTION

The present invention is directed to a light emitting device that includes a package defining a plurality of recesses in a lateral direction, and a plurality of light emitting units to be disposed in the recesses. The package with a shape elongated in a lateral direction includes at least three electrodes and a molded body. The at least three electrodes are arranged next to each other in the lateral direction to form the main portions of a bottom of the recesses. The at least three electrodes include a shared electrode which is electrically connected to the light emitting units respectively disposed in two adjacent recesses. The molded body is integrally formed with the at least three electrodes and defines the sidewalls of each recess.

At least one light emitting unit is disposed in each recess. Particularly, each light emitting unit is disposed on at least one of the two adjacent electrodes at the bottom of the recess. The molded body has at least one dividing portion separating two adjacent recesses in the lateral direction. The dividing portion partially covers the shared electrode electrically connected to two adjacent light emitting units.

An object of the present invention is to prevent deformation or even breakage of an elongated light emitting device by including a dividing portion to separate two adjacent recesses in a lateral direction and strengthen the mechanical structure of the elongated package of the light emitting device. Another object of the inventive light emitting device is to provide two or more light colors, each of which can be independently and separately turned on and off.

Another aspect of the inventive light emitting device is to maximize the brightness of the light emitting units and reduce the moisture contained in the light emitting device by the configuration of the adhesive used to affix the light emitting units on the bottom of the recesses.

Additional features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

### BRIEF DESCRIPTION OF THE DRAWINGS

FIG. 1 is a schematic view of the light emitting device according to one embodiment of the invention.

FIG. 2 is a schematic front view of the light emitting device according to one embodiment of the invention.

FIG. 3 is a schematic cross-sectional view taken along line A-A in FIG. 1.

FIG. 4 is a schematic bottom view of the light emitting device according to one embodiment of the invention.

FIG. 5 is a schematic view of the light emitting device whose external connection portion of the electrodes has a hole, according to one embodiment of the invention.

FIG. 6 is a schematic drawing illustrating the configuration of adhesive used to affix a light emitting unit on a substrate surface, according to one embodiment of the invention.

FIG. 7 is a schematic cross-sectional view of the light emitting device illustrating three light emitting units disposed in one recess, according to one embodiment of the invention.

FIG. 8 is a schematic cross-sectional view of the light emitting device illustrating additional electrodes to separately control multiple light emitting units disposed in one recess, according to one embodiment of the invention.

### DESCRIPTION OF THE PREFERRED EMBODIMENTS

The objectives, technical details, features, and effects of the present invention will be better understood with regard to the detailed description of the embodiments below, with reference to the drawings.

The terminology used in the description presented below is intended to be interpreted in its broadest reasonable manner, even though it is used in conjunction with a detailed description of certain specific embodiments of the technology. Certain terms may even be emphasized below; however, any terminology intended to be interpreted in any restricted manner will be specifically defined as such in this Detailed Description section.

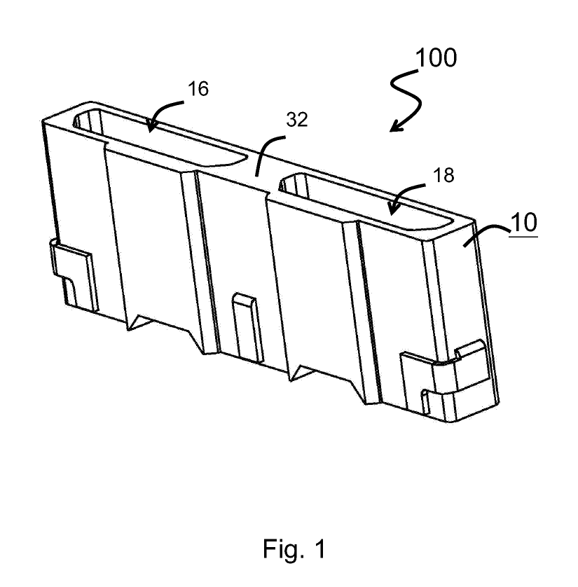

FIG. 1 is a schematic view of the light emitting device 100 according to one embodiment of the present invention. As shown in FIGS. 1-3, the light emitting device 100 includes a package 10 and light emitting units 12, 14. The light emitting device 100 and the package 10 have a laterally elongated shape (that is, elongated in the right-left direction in the drawings). The package 10 defines two recesses 16, 18. The recesses are formed to be elongated in the lateral direction similar to the package 10 having a laterally elongated shape. The package 10 includes three electrodes 20, 22, 24, and a molded body 30 integrally molded with the three electrodes 22, 24, 26, which are arranged next to each other in the lateral direction. The three electrodes 20, 22, 24 form main portions of the bottom of the recesses 16a, 18a. The molded body 30 structures the sidewalls of the recesses 16b, 18b. The shape of the recesses 16, 18 can be an oval, a polygon, a rectangle, etc. A skilled person knows how to choose an appropriate shape of the recesses to meet his/her needs and design rules.

The light emitting units 12, 14 are respectively accommodated in the recesses 16, 18. The light emitting units 12, 14 are essentially Lambertian sources which have a large beam divergence and a radiation pattern that approximate a sphere. The emitted light is reflected by the sidewalls 16b, 18b of the recesses, which can modify or maintain its full width at half maximum (FWHM) to make the light emitted from the two recesses 16, 18 overlap at least 20% to 100% with each other.

More specifically, the first light emitting unit 12 is disposed on at least the first electrode 20 or the second electrode 22 at the bottom of the first recess 16a. In other words, the first light emitting unit 12 can be disposed only on the first electrode 20, or only on the second electrode 22, or on both the first electrode 20 and the second electrode 22. The first light emitting unit 12 is then electrically connected to the pair of electrodes 20, 22 by wires 40. The second light emitting unit 14 is disposed on at least the second electrode 22 or the third electrode 24 at the bottom of the second recess 18a. The second light emitting unit 14 is electrically connected to the pair of electrodes 22, 24 by wires 42.

The second electrode 22 between the first electrode 20 and the third electrode 24 is a shared electrode, served as either a common cathode or a common anode, electrically connected to the first light emitting unit 12 and the second light emitting unit 14. The second electrode 22 is approximately disposed at the center of the package in the lateral direction of the light emitting device 100. The first and third electrodes 20, 24 are substantially symmetric with reference to the second electrode 22. Thus, with three electrodes, the first light emitting unit 12 and the second light emitting unit 14 can be separately and independently driven. The two light emitting units can emit light of the same of different hue, such as red, green, and blue.

Several benefits came with the feature of two separate recesses 16, 18 and at least three electrodes. First, because the two light emitting units 12, 14, are electrically connected in parallel, if one light emitting unit is broken, the other one can still work. Second, the interference of the light emitted from these two light emitting units can be reduced. Each recess can be filled with different wavelength conversion materials for providing various light colors.

In one embodiment, the light emitting device 100 is a side surface light emission type (side-view type). The recesses 16, 18 of the light emitting device 100 are formed in one side surface that is the front surface of the package 10. The molded body 30 can contain white pigment and filler, and exhibits light reflectivity particularly due to the white pigment. Accordingly, the shape of the light emitting region of the light emitting device 100 (unintended leaked light is not taken into consideration) substantially corresponds to the shape of the opening of the corresponding recesses 16, 18 at the front surface. The shape of the first light emitting region can be the same or different from the shape of the second light emitting region.

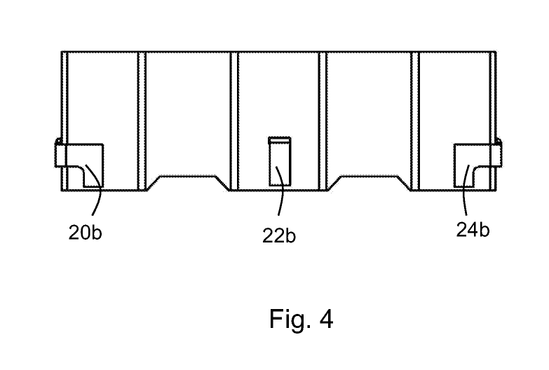

The bottom surface in the recess 16a is formed with a portion of the surface of the molded body 30 and the surfaces of the pair of electrodes 20, 22. These portions of the pair of electrodes 20, 22 that form the bottom surface of the recess 16a are unit mounting portions 20a, 22a. The wires 40 electrically connects the bonding regions of the light emitting units 12, 14 to the respective unit mounting portions 20a, 22a. Further, as shown in FIGS. 1 and 4, the three electrodes 20, 22, 24 have external connection terminal portions 20b, 22b, 24b which are the portions located outside the molded body 30. The external connection terminal portions 20b, 22b, 24b are bent along the bottom surface of the molded body 30. The light emitting device 100 is mounted by the external connection terminal portions 20b, 22b, 24b being soldered to the circuit board and the like. Hence, the mount-side surface of the light emitting device 100 (the package 10) is the bottom surface. More specifically, the bottom surface of the molded body 30 has a step respectively at the right end, center, and left end portions to dispose the external connection terminal portions 20b, 22b, 24b. That is to say, the bottom surface at the right end, middle, and left end portions are elevated with respect to the remaining portion of the bottom surface. Accordingly, the shape of the front of the package 10 (i.e., the molded body 30), and the shape of the opening of the recesses are formed such that the center portion of the recesses 16c, 18c is wider than the right and left portions (16r, 18r, 161, 181). In other words, the center portion has a greater longitudinal width than that of the right and left portions.

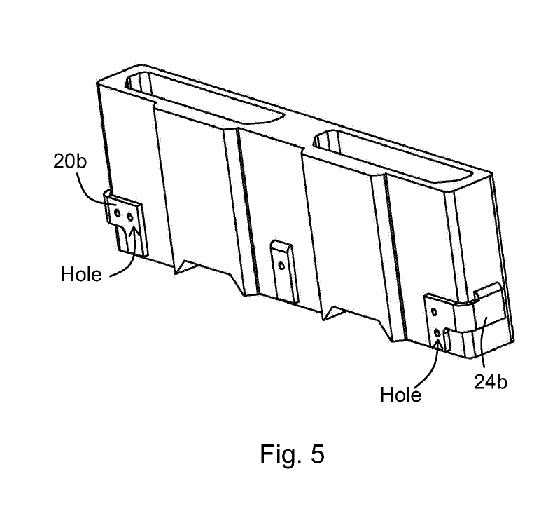

In one embodiment as shown in FIG. 5, the part of external connection terminal portions 20b, 22b, 24b of one or more of the three electrodes, which are bended underneath the bottom surface, can have one or more holes to enhance the solder ability. The hole can have an arbitrary shape. As a result, the light emitting device 100 can be sturdily affixed on a circuit board to reduce the movement and/or rotation of the light emitting device 100. A skilled person would know how to choose the appropriate number of holes and determine their shapes and sizes based on at least the geometries of the external connection terminal portions, in order to enhance the solder ability of the external connection terminal portions 20b, 22b, 24b. For example, each of the external connection terminal portions of the first and third electrodes 20b, 24b have two holes because they have a bigger surface area while the external connection terminal portion of the second electrode 22b has only one hole.

The molded body 30 has a dividing portion 32 that separates the first recess 16 from the second recess 18. The dividing portion 32 partially covers the second electrode 22. In one embodiment, the original second electrode 22 (before molded body is formed) has a T shape or the like, including a lateral portion 22a (at rectangular shape or the like) and a longitudinal portion 22c (at rectangular shape or the like). The lateral portion 22a of the second electrode further includes a first unit mounting portion 22a1 in the first recess 16, a second unit mounting portion 22a2 in the second recess 18, and a lateral embedded portion 22a3 that is surrounded by the dividing portion 32. A portion of the longitudinal portion of the second electrode outside of the package 10 is referred to as the external connection terminal portion 22b. The remaining portion of the second electrode is referred to as the internal portion which includes the lateral portion 22a and, a portion 22c of the longitudinal portion that is covered by the dividing portion 32.

In one embodiment, the dividing portion 32 covers more than 50% of the surfaces of the internal portion of the second electrode. The surfaces includes the front surface and back surface. The dividing portion 32 is aligned with the center of the lateral portion 22a of the second electrode, from the front view direction. Thus, the front surface area of first unit mounting portion 22a1 is approximately the same as that of the second unit mounting portion 22a2. In another embodiment, approximately 5%-80% of the front surface area of the internal portion of the second electrode (i.e. sum of the front surface areas of the first unit mounting portion 22a1 and the second unit mounting portion 22a2) is not covered by the dividing portion 32. Preferably, approximately 20%-60% of the front surface area of the internal portion of the second electrode is not covered by the dividing portion. In one embodiment, the lateral width of the narrowest part of the dividing portion 32 is larger than the lateral width of the longitudinal portion of the second electrode 22c inside the package.

The molded body 30 has two sidewalls 30b, 30c, opposite to each other in the longitudinal direction of the recesses 16, 18. In one embodiment, the distance between two sidewalls L(btw) is larger than the longitudinal width of the second electrode L(22a). As a result, a part of the longitudinal portion of the second electrode is also covered by the dividing portion 32.

Several factors can cause deformation of the package 10, including external force, temperature change due to heat applied in mounting using reflow soldering, and heat generated by the light emitting units 12, 14 and wavelength converting materials. In addition to the function of separating two recesses 16, 18, the dividing portion 32 can effectively enhance the mechanical strength of the molded body 30, so that the degree of deformation can be reduced. As a result, the dividing portion 32 can also facilitate obtaining of desired light distribution and stabilize the quality of the light emitting device 100.

After the molded body is formed, the light emitting units 12, 14 are respectively disposed on the bottom of the recesses 16a, 18a. The light emitted by the light emitting units 12, 14 is not limited to visible light. In other embodiments, the light emitted by the light emitting units 12, 14 can be invisible light, such as infrared light or UV light. The light emitting units 12, 14 can comprise any of of GaAs, AlAs, InAs, GaP, AlP, InP, ZnO, CdSe, CdTe, ZnTe, GaN, AlN, InN, Si, and any alloy, combination, or mixture thereof. The light emitting units 12, 14 can be of various types, such as horizontal type, vertical type, and a flip type. The light emitting units 12, 14 can be of various sizes that can fit into the recesses 16, 18. In one embodiment, the light emitting units 12, 14 are preferably of an unsquared shape. For example, both the lateral and longitudinal lengths of a light emitting unit can be smaller than 500 μm, such as 175 μm×250 μm, 250 μm×400 μm, 250 μm×300 μm, or 225 μm×175 μm approximately. In other embodiments, the light emitting unit can have at least the lateral length or the longitudinal length larger than 500 μm, such as 1000 μm×1000 μm, 500 μm×500 μm, 250 μm×600 μm, and 1500 μm×1500 μm approximately. In other embodiments, the light emitting units can be an even bigger length is approximately 3000 μm. In other embodiments, the light emitting units can be a micro LED whose length is usually smaller than 300 μm. In some embodiments, the light emitting units can be a micro LED whose length is usually smaller than 200 μm or even smaller than 100 μm, such as 225 μm×175 μm, 150 μm×100 μm, 150 μm×50 μm approximately. In some embodiments, the light emitting units can be a micro LED whose top surface area is smaller than 50,000 μm² or 10,000 μm². In some embodiments, the length of the light emitting units can be relatively large, such as at least 1000 μm or 3000 μm, where the top light emitting surface of the light emitting units is approximately 30%-70% of the light emitting region of the recesses.

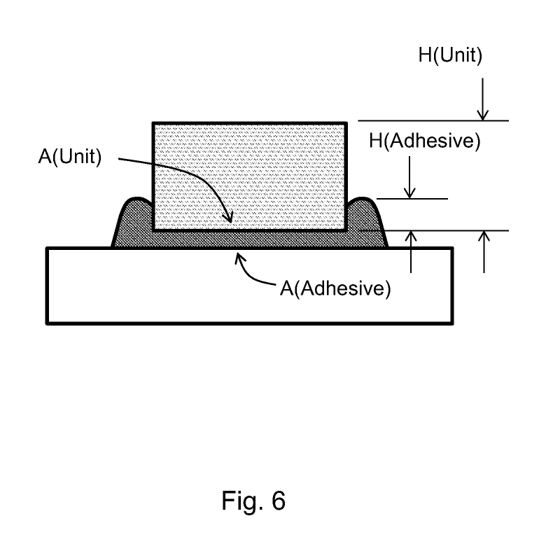

A micro dispensing process is regularly used to dispose the light emitting units 12, 14 respectively on the bottom of the recesses 16a, 18a. Micro dispensing is the technique of producing liquid media dosages, such as adhesive, glue, and grease, on a substrate surface in volumes of less than one microliter, reliably and accurately in dosage and placement with short cycle times. In one embodiment, the adhesive materials for affixing the light emitting units include Ag paste, silicone, epoxy, polymer, solder paste, and flux. After the adhesive is accurately dropped on a predetermined position of the substrate surface, a light emitting unit is disposed on top of the adhesive, which will then be forced to flow outwardly underneath the light emitting unit. The substrate can be a circuit board, an electrode 20a, 22a, 24a, and/or a bottom of the recess 16a, 18a. Depending on the amount of the adhesive dropped on the surface, the configuration of the adhesive, after the light emitting unit is affixed on the substrate, can vary and affect the brightness of the light emitting unit (i.e. the amount of light emitted from the light emitting unit). In one embodiment as shown in FIG. 6, the adhesive has a configuration that covers the surface area A(adhesive) under the light emitting unit and surrounds the light emitting unit averagely to the height H (adhesive) from the bottom surface of the light emitting unit. The adhesive surrounding the light emitting unit can block a portion of the light emitted from the side surface of the light emitting unit and cause side light loss. In addition, the larger adhesive area on the substrate surface can lead to more moisture stored inside the light emitting device 100 after encapsulation. However, insufficient adhesive can cause the light emitting unit to move or dis-attach from the substrate. In one embodiment, in order to balance the above factors and achieve optimal brightness of the light emitting unit, the adhesive surface area A(adhesive) ranges from 100% to 140% of the bottom surface area of the light emitting unit A(unit) and the adhesive height H(adhesive) ranges from 0% to 35% of the height of the light emitting unit H(unit). In such arrangement, the brightness of the affixed light emitting unit ranges from 100% to 120% of the brightness of the affixed light emitting unit where the adhesive surface area is about 121% to 140% of the bottom surface area of the light emitting unit and the adhesive height also ranges from 0% to 35% of the height of the light emitting unit. Preferably, the adhesive surface area A(adhesive) ranges from 100% to 120% of the bottom surface area of the light emitting unit A(unit) and the adhesive height H(adhesive) ranges from 0% to 35% of the height of the light emitting unit H(unit). The preferred arrangement can increase the brightness to 110%-120%.

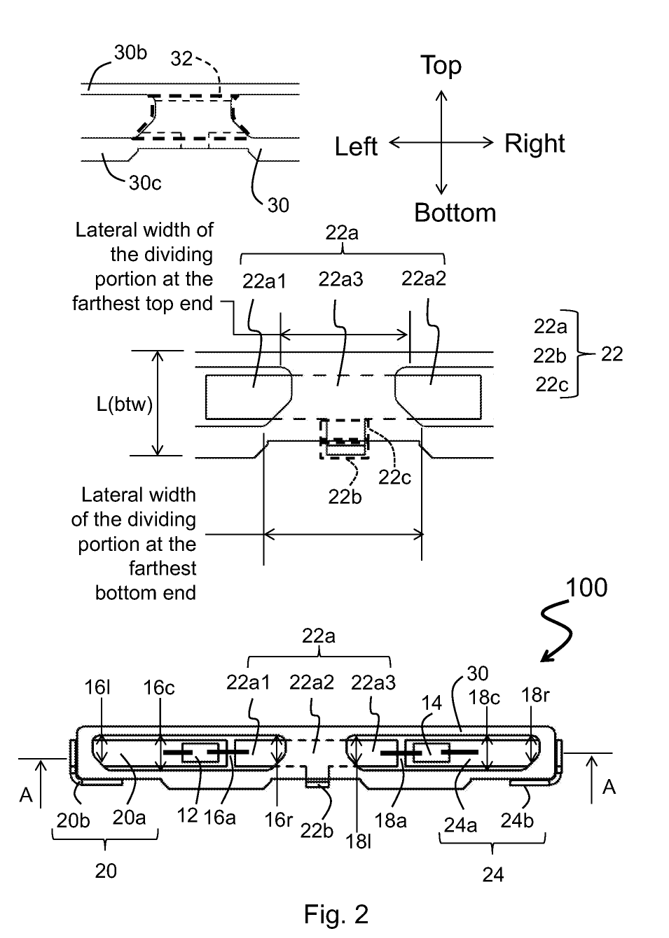

As shown in FIGS. 1 and 2, the light emitting device 100 includes the wires 40, 42. The wires 40 electrically connect the first light emitting unit 12 to both the first electrode 20 and the second electrode 22; the wires 42 electrically connect the second light emitting unit 14 to both the second electrode 22 and the third electrode 24. The wires 40 are accommodated in the first recess 16, and sealed by the sealing member 50. The wires 42 are accommodated in the second recess 18, and sealed by the sealing member 52. The wires 40, 42 preferably contain silver to improve the light reflectivity. That is, at least the surfaces of the wires 40, 42 are preferably made of silver or silver alloy and more preferably, the wires 40, 42 are made of silver or silver alloy. However, the wires 40, 42 may be distorted by expansion and contraction of the sealing members 50, 52, which may result in breakage of the wires 40, 42. The dividing portion 32 can enhance the mechanical strength of the molded body 30 which can then reduce the extent of expansion and contraction of the sealing members 50, 52. Thus, the wires 40, 42 would be less likely to be deformed or even broken.

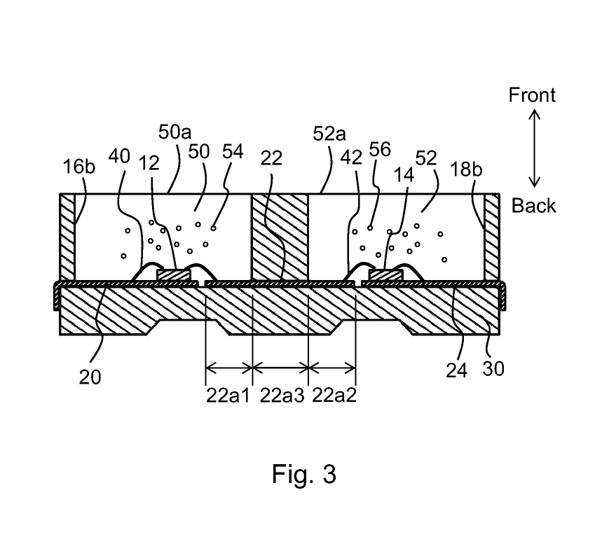

As shown in FIG. 3, the light emitting device 100 includes sealing members 50, 52 which are respectively filled in the recesses 16, 18. After encapsulation, the front surface of the first sealing member 50a is at approximately the same plane as the front surface of the second sealing member 52a. The difference between the first sealing member front surface 50a and the second sealing member front surface 52a can be managed not to exceed 20% of the depth of the recesses 16, 18 (measured from the bottom of the recess to the front surface of the molded body). As a result, the light emitting device 100 can provide stabilized shape of light.

The sealing members 50, 52 respectively contain a wavelength converting substance 54, 56 to convert the light emitted by the light emitting units 12, 14 into light of different wavelength. Each of the wavelength converting substances 54, 56 can include a plurality of fluorescent materials. For example, the wavelength converting substance 54, 56 can include a first fluorescent material 60 to emit green to yellow light, and a second fluorescent material 62 to emit red light, when both light emitting units 12, 14 emit blue light. Such a configuration can achieve good color reproducibility or good color rendering. However, since the amount of the wavelength converting materials 60, 62 used is increased, the heat generation due to Stokes' loss also increases. Such heat may deform the molded body 30 and/or the sealing members 50, 52 of the package. The dividing portion 32 can effectively prevent the deformation.

The base material of the sealing member 30 can be ceramic material or resin material. Epoxy resin can also be used. The ceramic material preferably can be cerium dioxide. the resin material preferably can be silicone-based resin containing a phenyl group. Silicone-based resin is thermosetting resin and exhibits good heat resistance and lightfastness, and inclusion of a phenyl group can further enhance the heat resistance. Since silicone-based resin that contains a phenyl group exhibits a relatively great gas barrier characteristic among silicone-based resins, deterioration due to moisture of the manganese-activated fluoride fluorescent material can be easily reduced. The fluoride fluorescent material activated with manganese can reduce deterioration due to moisture and heat, so that the fluoride fluorescent material activated with manganese is preferably arranged in the sealing member 30 with a greater amount in the back-side portion than in the front-side portion. That is, the fluoride fluorescent material activated with manganese is arranged with a greater amount in the vicinity of the bottom side of the recess 10a.

The fluorescent materials can be selected from a group consisting of: (Sr,Ba)Si2(O,Cl)2N2:Eu2+; Sr5(PO4)3Cl:Eu2+; (Sr,Ba)MgAl10O17:Eu2+; (Sr,Ba)3MgSi2O8:Eu2+; SrAl2O4:Eu2+; SrBaSiO4:Eu2+; CdS:In; CaS:Ce3+; (Y,Lu,Gd) 3(Al,Ga)5O12:Ce3+; Ca3Sc2Si3O12:Ce3+; SrSiON:Eu2+; ZnS:Al3+,Cu+; CaS:Sn2+; CaS:Sn2+,F; CaSO4:Ce3+,Mn2+; LiAlO2:Mn2+; BaMgAl10O17:Eu2+,Mn2+; ZnS:Cu+,Cl−; Ca3WO6:U; Ca3SiO4Cl2:Eu2+; SrxBayClzAl2O4-z/2:Ce3+,Mn2+(X:0.2; Y:0.7; Z:1.1); Ba2MgSi2O7:Eu2+; Ba2SiO4:Eu2+; Ba2Li2Si2O7:Eu2+; ZnO:S; ZnO:Zn; Ca2Ba3(PO4)3Cl:Eu2+; BaAl2O4:Eu2+; SrGa2S4:Eu2+; ZnS:Eu2+; Ba5(PO4)3Cl:U; Sr3WO6:U; CaGa2S4:Eu2+; SrSO4:Eu2+,Mn2+; ZnS:P; ZnS:P3−,Cl−; ZnS:Mn2+; CaS:Yb2+,Cl; Gd3Ga4O12:Cr3+; CaGa2S4:Mn2+; Na(Mg,Mn)2LiSi4O10F2:Mn; ZnS:Sn2+; Y3Al5O12:Cr3+; SrB8013:Sm2+; MgSr3Si2O8:Eu2+,Mn2+; α-SrO.3B2O3:Sm2+; ZnS—CdS; ZnSe:Cu+,Cl; ZnGa2S4:Mn2+; ZnO:Bi3+; BaS:Au,K; ZnS:Pb2+; ZnS:Sn2+,Li+; ZnS:Pb,Cu; CaTiO3:Pr3+; CaTiO3:Eu3+; Y2O3:Eu3+; (Y,Gd)2O3:Eu3+; CaS:Pb2+,Mn2+; YPO4:Eu3+; Ca2MgSi2O7:Eu2+,Mn2+; Y(P,V)O4:Eu3+; Y2O2S:Eu3+; SrAl4O7:Eu3+; CaYAlO4:Eu3+; LaO2S:Eu3+; LiW2O8:Eu3+,Sm3+; (Sr,Ca,Ba,Mg)10(PO4)6Cl2:Eu2+,Mn2+; Ba3MgSi2O8:Eu2+,Mn2+; ZnS:Mn2+,Te2+; Mg2TiO4:Mn4+; K2SiF6:Mn4+; SrS:Eu2+; Na1.23K0.42Eu0.12TiSi4O11; Na1.23K0.42Eu0.12TiSi5O13:Eu3+; CdS:In,Te; (Sr,Ca)AlSiN3:Eu2+; CaSiN3:Eu2+; (Ca,Sr)2Si5N8:Eu2+; and Eu2W2O7. Because some fluorescent materials have poor resistance to water vapor, in order to increase the reliability of the light emitting device 100, the base material preferably can have a water vapor permeability below 10.5 g/m²/24 hr and an oxygen permeability below 382 cm³/m²/24 hr to improve its resistance to hydrolysis and degradation.

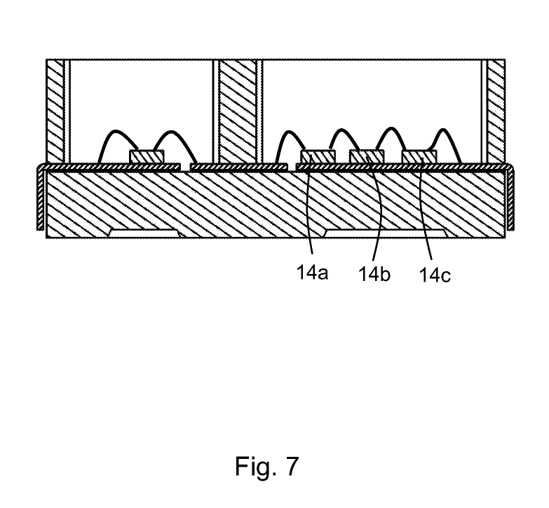

In another embodiment as shown in FIG. 7, a plurality of light emitting units can be disposed in at least the first recess 16 or the second recess 18. For example, three light emitting units 14a, 14b, 14c are disposed on at least the second electrode 22 or the third electrode 24 on the bottom of the second recess 18a. The three light emitting units 14a-c are electrically connected to both the second electrode 22 and the third electrode 24 in series. In this embodiment, all three light emitting units 14a-c have to be driven simultaneously. In one embodiment, the three light emitting units 14a-c remit respectively red, green, and blue light to provide white light. However, the three light emitting units 14a-c can be driven separately and independently from the first light emitting unit 12.

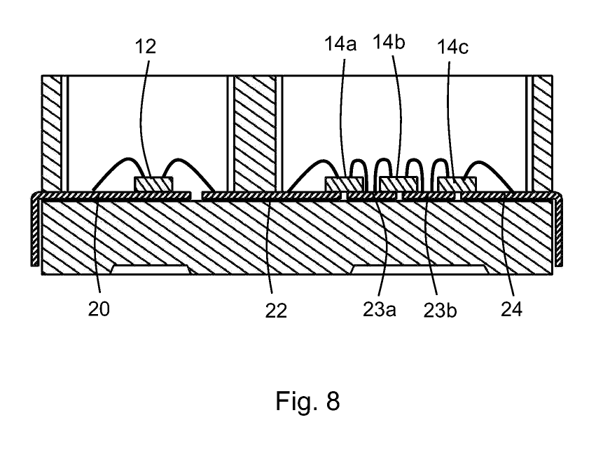

In another embodiment as shown in FIG. 8, in order to separately drive the three light emitting units 14a-c disposed on at least the second electrode 22 or the third electrode 24 on the bottom of the first recess 18a, two additional electrodes 23a, 23b are arranged between the second electrode 22 and the third electrode 24. In one embodiment, the lateral width sequentially between the second electrode 22, the first additional electrode 23a, the second additional electrode 23b, and the third electrode 24 can be approximately the same. The first additional electrode 23a is a common electrode (either cathode or anode) shared by the light emitting units 14a and 14b. The second additional electrode 23b is a common electrode (either cathode or anode) shared by the light emitting units 14b and 14c.

The present invention has been described in considerable details with reference to various embodiments thereof. Such description is for illustrative purpose, not for limiting the scope of the present invention. It will be apparent to those skilled in the art that various modification and variations can be made in the methods and related apparatus and systems of the present invention without departing from the spirit or scope of the invention. Thus, it is intended that the present invention cover modifications and variations that come within the scope of the appended claims and their equivalents.

What is claimed is:

1. A light emitting device, comprising:
a package, defining a plurality of recesses in a lateral direction, and including at least three electrodes and a molded body;
a plurality of light emitting units, each of which is disposed at a bottom of a recess and electronically connected to two adjacent electrodes;
wherein the at least three electrodes are arranged next to each other in the lateral direction to form the main portions of the bottom of the recesses, and comprise at least one shared electrode which is electrically connected to the light emitting units respectively disposed in two adjacent recesses; and
wherein the molded body, integrally formed with the at least three electrodes, defines the sidewalls of each recess and has at least one dividing portion separating two adjacent recesses, the dividing portion partially covering the shared electrode.

2. The light emitting device of claim 1, wherein the plurality of light emitting units can emit light of more than one color.

3. The light emitting device of claim 1, wherein two or more light emitting units are disposed at the bottom of a single recess.

4. The light emitting device of claim 3, wherein the two or more light emitting units disposed at the bottom of a single recess are electrically connected in series.

5. The light emitting device of claim 1, wherein the shared electrode includes an internal portion and an external portion; and the external portion serves as a connection terminal of the package.

6. The light emitting device of claim 5, wherein the dividing portion covers more than 50% of the surface area of the internal portion of the shared electrode.

7. The light emitting device of claim 5, wherein approximately 5%-80% of the front surface area of the internal portion of the shared electrode is not covered by the dividing portion.

8. The light emitting device of claim 5, wherein approximately 20%-60% of the front surface area of the internal portion of the shared electrode is not covered by the dividing portion.

9. The light emitting device of claim 1, wherein the shared electrode has a lateral portion and a longitudinal portion; and the lateral portion includes a first unit mounting portion, a second unit mounting portion, and a lateral embedded portion which is covered by the dividing portion of the molded body.

10. The light emitting device of claim 9, wherein the lateral width of the narrowest part of the lateral embedded portion of the shared electrode is larger than the lateral width of the longitudinal portion of the shared electrode.

11. The light emitting device of claim 9, wherein the distance between two sidewalls of the molded body is larger than the longitudinal width of the lateral portion of the shared electrode.

12. The light emitting device of claim 9, wherein the front surface area of the first unit mounting portion of the shared electrode is approximately the same as the front surface area of the second unit mounting portion of the second electrode.

13. The light emitting device of claim 1, wherein the lateral width of the dividing portion at the farthest top end is smaller than the lateral width of the dividing portion at the farthest bottom end.

14. A light emitting device, comprising:
a package, defining a first recess and a second recess in a lateral direction, and including a first electrode, a second electrode, and a third electrode and a molded body;
a first light emitting unit and a second light emitting unit respectively disposed at a bottom of the first recess and the second recess;
wherein the electrodes are arranged next to each other in the lateral direction to form the main portions of the bottom of the recesses, and the second electrode is electrically connected to the first light emitting unit and the second light emitting unit;
wherein the molded body, integrally formed with the three electrodes, defines the sidewalls of each recess and has one dividing portion separating the first recess from the second recess, the dividing portion partially covering the second electrode; and
the second electrode with approximately a T shape, includes a lateral portion and a longitudinal portion; and
the lateral portion includes a first unit mounting portion, a second unit mounting portion, and a lateral embedded portion which is covered by the dividing portion of the molded body.

15. The light emitting device of claim 14, wherein the lateral width of the narrowest part of the lateral embedded portion of the second electrode is larger than the lateral width of the longitudinal portion of the second electrode.

16. The light emitting device of claim 14, wherein the lateral width of the dividing portion at the farthest top end is smaller than the lateral width of the dividing portion at the farthest bottom end.
